(19) United States
(12) Patent Application Publication
(10) Pub. No.: US 2016/0204314 A1
(43) Pub. Date: Jul. 14, 2016

(54) LIGHT EMITTING DIODE PACKAGE

(71) Applicant: SAMSUNG ELECTRONICS CO., LTD., Suwon-si (KR)

(72) Inventors: Yun Tae HWANG, Seoul (KR); Il Woo PARK, Suwon-si (KR); Young Sim O, Suwon-si (KR); Daseul YU, Hwaseong-si (KR); Jae Sung YOU, Hwaseong-si (KR); Chang Bun YOON, Gwangmyeong-si (KR)

(73) Assignee: SAMSUNG ELECTRONICS CO., LTD., Suwon-si (KR)

(21) Appl. No.: 14/973,996

(22) Filed: Dec. 18, 2015

(30) Foreign Application Priority Data
Jan. 12, 2015 (KR) 10-2015-0004356

(51) Int. Cl. H01L 33/46; H01L 33/48; H01L 33/58; H01L 33/50; H01L 33/38

(52) U.S. Cl. CPC H01L 33/46; H01L 33/502; H01L 33/38; H01L 33/505; H01L 33/58; H01L 33/486

(57) ABSTRACT

A light emitting diode (LED) package includes: a package substrate having a first electrode structure and a second electrode structure; an LED chip disposed above a first surface of the package substrate and having a first electrode attached to the first electrode structure and a second electrode attached to the second electrode structure; a reflective layer disposed above the first surface of the package substrate to be separated from the LED chip, having a thickness less than a thickness of the LED chip, and configured to reflect light emitted from the LED chip to a given direction, wherein the wavelength converter has an upper surface substantially parallel to the first surface of the package substrate and a side surface inclined towards the upper surface of the wavelength converter.

### CROSS-REFERENCE TO THE RELATED APPLICATION

This application claims priority from Korean Patent Application No. 10-2015-0004356 filed on Jan. 12, 2015, with the Korean Intellectual Property Office, the disclosure of which is incorporated herein in its entirety by reference.

### TECHNICAL FIELD

Apparatuses consistent with exemplary embodiments of the inventive concept relate to an LED package.

### BACKGROUND

In general, an LED is a device in which a substance contained therein emits light when electrical energy is applied thereto. In such a device, energy generated when electrons and holes are recombined at junctions between semiconductor layers is converted to light, so that light may be emitted from the LED. Such LEDs are widely used in lighting devices and display devices and used as light sources, and accordingly, the development thereof is seeing rapid growth.

In particular, as the development and the use of gallium nitride (GaN)-based LEDs have expanded, and as cell phone keypads, turn signal lamps, camera flashes, and the like, using gallium nitride (GaN) LEDs as the light sources thereof, have been commercialized, the development of general lighting devices has also been accelerated. As LEDs used as light sources in devices such as automobile headlights and backlight units of big-screen TVs, general lighting devices, applications thereof, and the like are being increased in size, as well as being increased in both capacity and efficiency, a method of improving light extraction efficiency of such LEDs is required.

### SUMMARY

Exemplary embodiments of the inventive concept provide a light emitting diode (LED) package having improved color quality.

According to an exemplary embodiment, there is provided an LED package which may include: a package substrate having a first electrode structure and a second electrode structure; an LED chip disposed above a first surface of the package substrate and having a first electrode attached to the first electrode structure and a second electrode attached to the second electrode structure; a reflective layer disposed above the first surface of the package substrate to be separated from the LED chip, having a thickness less than a thickness of the LED chip, and configured to reflect light emitted from the LED chip to a given direction, wherein the wavelength converter has an upper surface substantially parallel to the first surface of the package substrate and a side surface inclined towards the upper surface of the wavelength converter.

A distance between a side end of the LED chip closest to the reflective layer and the reflective layer in a direction parallel with the first surface of the package substrate may range from about 50 μm to about 150 μm.

A thickness of the reflective layer may range from about 20 μm to about 60 μm.

The reflective layer may contain at least one of SiO₂, SiN, SiOₓN_{q}, TiO₂, Si₃N₄, Al₂O₃, TiN, AlN, ZrO₂, TiAlN, and TiSiN.

The inclined side surface of the wavelength converter may have an angle of inclination ranging from about 9.5° to about 36°, inclined in a direction from a bottom of the wavelength converter towards the upper surface of the wavelength converter with respect to the first surface of the package substrate.

A portion of the wavelength converter at which the upper surface of the wavelength converter and the side surface of the wavelength converter are connected may be curved.

The reflective layer may be disposed to come into contact with the inclined side surface of the wavelength converter and to extend outwardly from the wavelength converter, based on the LED chip, and at least a portion of the reflective layer may not be covered by the wavelength converter.

A side of the LED chip may be covered by the wavelength converter.

The wavelength converter may be formed of a light transmitting material in which a wavelength conversion material is dispersed.

The light transmitting material may be a material selected from the group consisting of silicone, modified silicone, an epoxy, a urethane, oxetane, an acryl, a polycarbonate, a polyimide, and combinations thereof.

The wavelength conversion material may be a phosphor or a quantum dot.

The LED package may further include a lens covering the wavelength converter.

A width of the wavelength converter may be greater than a width of the LED chip by about 1.3 times to about 3.7 times.

According to another exemplary embodiment, there is provided an LED package which may include: a package substrate, an LED chip mounted on a first surface of the package substrate, a reflective layer disposed above the first surface of the package substrate to be spaced apart from the LED chip by a predetermined distance, and configured to reflect light emitted from the LED chip to a given direction; and a wavelength converter covering the LED chip and at least a portion of the reflective layer, having a side surface inclined downwardly towards the first surface of the package substrate, and configured to convert a wavelength of the light emitted from the LED chip.

The light emitting diode chip may be mounted on the first surface of the package substrate in a flip-chip structure.

### BRIEF DESCRIPTION OF DRAWINGS

The above and other aspects, features and advantages of the inventive concept will be more clearly understood from the following detailed description taken in conjunction with the accompanying drawings, in which:

FIG. 1 is a perspective view of an LED package according to an exemplary embodiment;

FIG. 2 is a plan view of the LED package of FIG. 1, according to an exemplary embodiment;

FIG. 3 is a cross-sectional view of the LED package taken along line A-A′ of FIG. 1, according to an exemplary embodiment;

FIG. 4 is an enlarged view illustrating an LED chip of FIG. 1, according to an exemplary embodiment;

FIGS. 5 to 8 are schematic views illustrating a process of manufacturing the LED package of FIG. 1, according to exemplary embodiments;

FIG. 9 is a schematic cross-sectional view illustrating an example of a backlight having the LED package of FIG. 1, according to an exemplary embodiment;

FIG. 10 is a schematic cross-sectional view illustrating another example of a backlight having the LED package of FIG. 1, according to an exemplary embodiment;

FIG. 11 is a view illustrating an example of a lighting device having the LED package of FIG. 1, according to an exemplary embodiment; and

FIG. 12 is a view illustrating an example of a vehicle headlamp having the LED package of FIG. 1, according to an exemplary embodiment.

### DETAILED DESCRIPTION OF THE EXEMPLARY EMBODIMENTS

Various exemplary embodiments of the inventive concept will now be described more fully with reference to the accompanying drawings. The inventive concept may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the embodiments set forth herein.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when an embodiment can be implemented differently, functions or operations described in a particular block may occur in a different way from a flow described in the flowchart. For example, two consecutive blocks may be performed simultaneously, or the blocks may be performed in reverse according to related functions or operations.

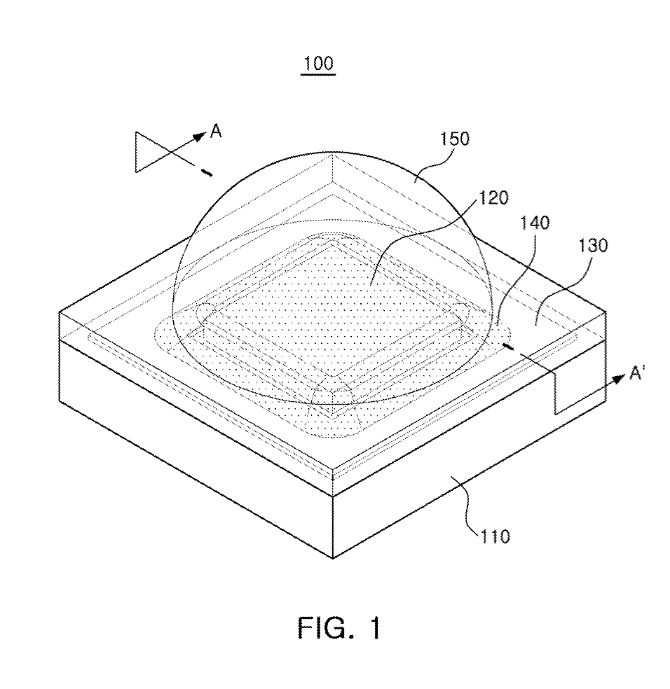

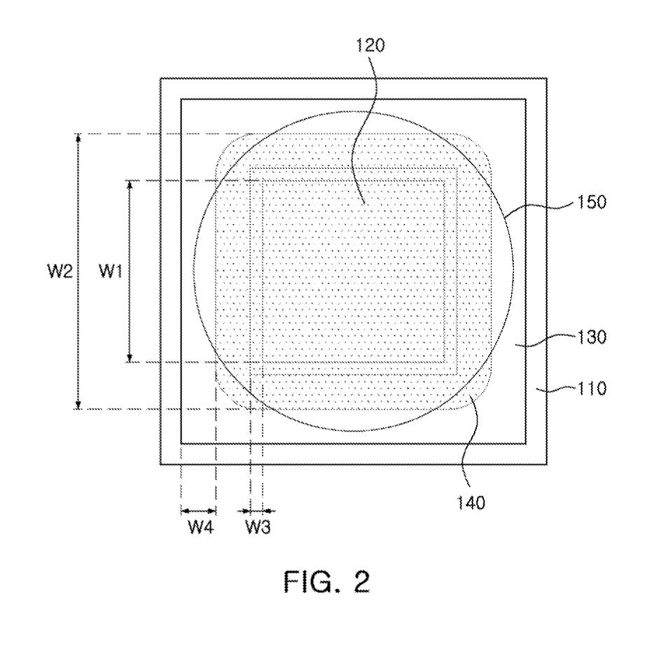

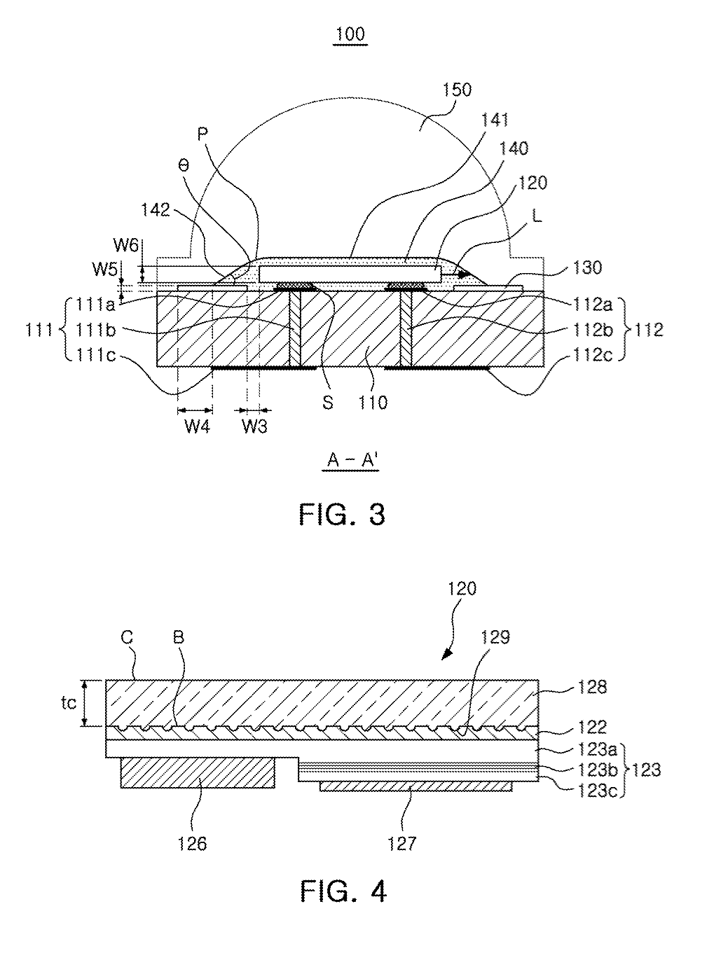

FIG. 1 is a perspective view of a light emitting diode (LED) package according to an exemplary embodiment, and FIG. 2 is a plan view of the LED package of FIG. 1, according to an exemplary embodiment. FIG. 3 is a cross-sectional view of the LED package taken along line A-A′ of FIG. 1, according to an exemplary embodiment, and FIG. 4 is an enlarged view illustrating an LED chip of FIG. 1, according to an exemplary embodiment.

Referring to FIGS. 1 to 3, an LED package 100 according to an exemplary embodiment may include a package substrate 110 having a first electrode structure 111 and a second electrode structure 112, an LED chip 120 mounted on the package substrate 110, a reflective layer 130 disposed on the package substrate 110, and a wavelength converter 140 disposed on the package substrate 110.

As illustrated in FIG. 3, the package substrate 110 may have the first electrode structure 111 and the second electrode structure 112. A first via electrode 111b in the first electrode structure 111 and a second via electrode 112b in the second electrode structure 112 may be formed to penetrate from one surface of the package substrate 110 on which the LED chip may be mounted to the other surface thereof opposing the one surface, in a thickness direction of the package substrate 110. First bonding pads 111a and 111c may be respectively disposed on the one surface and the other surface of the package substrate 110 to which both end portions of the first via electrode 111b are exposed, and second bonding pads 112a and 112c may be respectively disposed on the one surface and the other surface of the package substrate 110 to which both end portions of the second via electrode 112b may be exposed, so that both surfaces of the package substrate 110 may be electrically connected to each other.

The package substrate 110 may be manufactured using a substrate formed of a substance such as Si, Sapphire, ZnO, GaAs, SiC, MgAl₂O₄, MgO, LiAlO₂, LiGaO₂, GaN, and the like. According to an exemplary embodiment, a substrate formed of Si may be used, but the material forming the package substrate 110 is not limited thereto. Thus, depending on heat-radiating characteristics and electrical connectivity of the manufactured LED package, the substrate may be formed of a material such as an organic resin material containing an epoxy, a triazine, a silicone, a polyimide, and the like, and other organic resin materials. In addition, in order to improve heat-radiating characteristics and light-emitting efficiency, the package substrate 110 may be formed of a ceramic material such as Al₂O₃ and AlN, and the like having high heat-resistance properties, great heat-conduction properties, superior reflection efficiency, and the like.

Further, in addition to the aforementioned substrate, a printed circuit board (PCB), a lead frame, or the like may be used as the package substrate 110 according to an exemplary embodiment.

An LED chip 120 may be mounted on one surface of the package substrate 110.

Referring to FIG. 4, the LED chip 120 may include a light transmitting substrate 128 having a first surface B and a second surface C opposing the first surface B, a light emitting structure 123 disposed on the first surface B of the substrate 128, and a first electrode 126 and a second electrode 127 connected to the light emitting structure 123, respectively.

As the substrate 128, a substrate for semiconductor growth formed of a material such as sapphire, SiC, MgAl₂O₄, MgO, LiAlO₂, LiGaO₂, and GaN may be used. In this case, the sapphire is a crystal having Hexa-Rhombo (Hexa-Rhombo R3c) symmetry, and a lattice constant of 13.001 Å in a c-axis orientation and a lattice constant of 4.758 Å in an a-axis orientation. Here, the sapphire has a C plane (0001), an A plane (11-20), an R plane (1-102), and the like. In this case, since the C-plane allows a nitride thin film to be relatively easily grown thereon and is stable even at high temperatures, sapphire is predominantly utilized as a growth substrate for a nitride.

An unevenness portion 129 may be formed on at least one of the first surface B and the second surface C of the substrate 128. The unevenness portion 129 may be formed by etching portions of the substrate 128 or forming a hetero-material different from that of the substrate 128.

When the unevenness portion 129 is formed on the first surface B provided for the growth of the light emitting structure 123, as illustrated in FIG. 4, stress incurred due to a difference in lattice constants between the substrate 128 and a first conductivity-type semiconductor layer 123a may be relieved. In detail, when a group III nitride-based compound semiconductor layer is grown on a sapphire substrate, a lattice defect such as a dislocation may be incurred due to the difference in lattice constants between the substrate and the group III nitride-based compound semiconductor layer, and such a lattice defect may spread to an upper portion, thereby deteriorating the crystallinity of the semiconductor layer.

According to an exemplary embodiment, a dislocation defect may be prevented from spreading to an upper portion by forming the unevenness portion 129 having convex portions on the substrate 128 so that the first conductivity-type semiconductor layer 123a may grow on a side surface of the convex portion. Thus, a higher-quality LED package may be provided, and internal quantum efficiency may be improved.

In addition, paths of light emitted from an active layer 123b may be diversified by the unevenness portion 129. Thus, the proportion of the light being absorbed inside the semiconductor layer may decreased, and the degree of light scattering may be increased, such that light extraction efficiency may be improved.

Here, the substrate 128 may have a thickness (tc) of 100 μm or less. In detail, the substrate 128 may have a thickness ranging from 1 μm to 20 μm, but is not limited thereto. This range of thickness may be obtained by polishing a growth substrate provided for a semiconductor growth. In detail, a method of grinding the second surface C opposing the first surface B on which the light emitting structure 123 is formed or a method of lapping the second surface C using a lap and lapping powder through grinding and abrasion may be used.

The light emitting structure 123 may include the first conductivity-type semiconductor layer 123a, the active layer 123b, and a second conductivity-type semiconductor layer 123c, which are disposed sequentially on the first surface B of the substrate 128. The first conductivity-type semiconductor layer 123a and the second conductivity-type semiconductor layer 123c may respectively be an n-type semiconductor layer and a p-type semiconductor layer and may be configured of a nitride semiconductor. According to an exemplary embodiment, the first conductivity-type semiconductor layer 123a and the second conductivity-type semiconductor layer 123c may be understood to refer to an n-type nitride semiconductor layer and a p-type nitride semiconductor layer respectively, but are not limited thereto. The first conductivity-type semiconductor layer 123a and the second conductivity-type semiconductor layer 123c may be represented by an empirical formula AlₓIn_{y}Ga_{(1-x-y)}N (0≦x<1, 0≦y<1, and 0≦x+y<1), and materials such as GaN, AlGaN, InGaN, and the like may correspond thereto.

The active layer 123b may be a layer for emitting visible light having a wavelength ranging from about 350 nm to 680 nm and may be configured of an undoped nitride semiconductor layer having a single quantum well structure or multiple quantum well (MQW) structure. For example, the active layer 123b may be formed to have a multiple quantum well structure in which multiple quantum barrier layers and multiple quantum well layers corresponding to AlₓIn_{y}Ga_{(1-x-y)}N (0≦x<1, 0≦y<1, and 0≦x+y<1) are alternately laminated, and may have a structure having a predetermined band gap. Electrons and holes are recombined by the quantum well structure to emit light. For example, InGaN/GaN structure may be used for the multiple quantum well structure. The first conductivity-type semiconductor layer 123a, the second conductivity-type semiconductor layer 123c, and the active layer 123b may be formed using a crystal growth process such as metal organic chemical vapor deposition (MOCVD), molecular beam epitaxy (MBE), hydride vapor phase epitaxy (HYPE), and the like.

A buffer layer 122 may be further disposed between the substrate 128 and the light emitting structure 123. In a case in which the light emitting structure 123 is grown on the substrate 128, for example, in a case in which a GaN thin film is grown as the light emitting structure on a hetero-substrate, a lattice defect such as a dislocation may occur due to the difference in lattice constants between the substrate and the GaN thin film, and cracking may appear in the light emitting structure because the substrate is bent due to the difference in thermal expansion coefficients between the substrate and the GaN thin film. In order to prevent the lattice defect and the bending from occurring, the buffer layer 122 may first be formed on the substrate 128, and then a desired light emitting structure such as a nitride semiconductor may be grown on the buffer layer 122. Such a buffer layer 122 may be a low temperature buffer layer formed at a temperature lower than a growth temperature of a single crystal forming the light emitting structure 123, but is not limited thereto.

As a material of the buffer layer 122, AlₓIn_{y}Ga_{(1-x-y)}N (O≦x≦1, 0≦y≦1), in further detail, GaN, AlN, AlGaN, or the like may be used. For example, the buffer layer may be formed of an undoped GaN layer not doped with an impurity and having a predetermined thickness, but is not limited thereto.

Thus, any structure able to improve crystallinity of the light emitting structure 123 may be adopted, and substances such as ZrB₂, HfB₂, ZrN, HfN, TiN, ZnO, and the like may also be used. In addition, a layer in which a plurality of layers are mixed or a layer in which a composition is gradually changed may be used.

The first electrode 126 may be provided to form an external electrical connection of the first conductivity-type semiconductor layer 123a, and the second electrode 127 may be provided to form an external electrical connection of the second conductivity-type semiconductor layer 123c. The first electrode 126 and the second electrode 127 may be disposed to come into contact with the first conductivity-type semiconductor layer 123a and the second conductivity-type semiconductor layer 123c, respectively.

In the first electrode 126 and the second electrode 127, a conductive material thereof having a characteristic of ohmic contact with the first conductivity-type semiconductor layer 123a and the second conductivity-type semiconductor layer 123c, respectively, and having a single-layer or a multilayer structure may be used. For example, the first electrode 126 and the second electrode 127 may be formed using a process of deposition or sputtering using one or more of Au, Ag, Cu, Zn, Al, In, Ti, Si, Ge, Sn, Mg, Ta, Cr, W, Ru, Rh, Ir, Ni, Pd, Pt, transparent conductive oxide (TCO), and the like. The first electrode 126 and the second electrode 127 may be disposed in a single direction under the light emitting structure 123 on which the substrate 128 is disposed, and may be mounted in a so-called flip-chip structure with the first electrode structure 111 and the second electrode structure 112 of the package substrate 110. The first electrode 126 may be electrically connected to the first electrode structure 111, and the second electrode 127 may be electrically connected to the second electrode structure 112 through a conductive binder material S, and as the conductive binder material, a solder bump containing tin (Sn) may be used. As described above, when the LED chip is mounted on the package substrate 110 in the flip-chip structure, the light emitted from the active layer 123b may be discharged outwardly via the substrate 128.

The reflective layer 130 may be disposed on one surface of the package substrate 110 on which the LED chip 120 is mounted. The reflective layer 130 may be configured in a single-layer structure or a multilayer structure and may be formed using at least one selected from a group consisting of SiO₂, SiN, SiOₓN_{y}, TiO₂, Si₃N₄, Al₂O₃, TiN, AlN, ZrO₂, TiAlN and TiSiN.

The reflective layer 130 may be disposed on one surface of the package substrate 110 on which the LED chip 120 is mounted and have a thickness W5 less than a thickness W6 of the LED chip 120. Here, the thickness of the reflective layer 130 may be reduced so that the reflective layer 130 may not be disposed in an optical path of side light L emitted from the LED chip 120. For example, the reflective layer 130 may have a thickness ranging from about 20 μm to about 60 μm. Also, for example, the optical path of the side light L may be parallel with the one surface of package substrate 110.

In addition, the reflective layer 130 may be disposed to cover one surface of the package substrate 110 and be spaced apart from the LED chip 120 by a predetermined distance W3 when viewed from above the LED package 100. In detail, as illustrated in FIG. 2 and FIG. 3, on one surface of the package substrate 110, the reflective layer 130 may not be disposed on a portion of the one surface of the package substrate 110 having a predetermined distance W3 from a side of the LED chip 120 to an end of the reflective layer in a direction parallel to the one surface of the package substrate 110. This is to prevent the side of the LED chip 120 from coming into contact with the reflective layer 130. In a case in which the reflective layer 130 is disposed to come into contact with the side of the LED chip 120, a portion of the side light L from LED package 100 may be discharged outwardly without passing through the wavelength converter 140. Thus, according to the present exemplary embodiment, the problem may be resolved by disposing the reflective layer 130 to be spaced apart from the LED chip 120 by the predetermined distance W3.

The predetermined distance W3 may be a minimum distance to allow the wavelength converter 140 to be spread on portions between the reflective layer 130 and the LED chip 120 during a manufacturing process. In a case in which the wavelength converter 140 is not spread on the portions between the reflective layer 130 and the LED chip 120, a cavity may be formed in a lower portion of the wavelength converter 140. For example, the predetermined distance W3 may range from about 50 μm to about 150 μm. In a case in which the predetermined distance W3 is less than about 50 μm, the wavelength converter 140 may not be spread, and thus a cavity may be formed in a lower portion of the wavelength converter 140, while in a case in which the predetermined distance W3 is greater than about 150 μm, a portion in which the reflective layer 130 is not disposed may be excessively increased in the lower portion of the wavelength converter 140, and thus the light extraction efficiency of the LED package may be decreased.

In addition, the reflective layer 130 may have a thickness W5 sufficient, not to interrupt the optical path of the side light L emitted from the LED chip 140. For example, the reflective layer 130 may have a thickness ranging from about 20 μm to about 60 μm. In a case in which the thickness W5 of the reflective layer 130 is less than about 20 μm, the reflectance of the reflective layer 130 may be significantly decreased, and thus the light extraction efficiency of the LED package may be decreased. On the other hand, in a case in which the thickness W5 of the reflective layer 130 is greater than about 60 μm, cracking may appear in a surface of contact between the reflective layer 130 and the wavelength converter 140 due to a difference in thermal expansion coefficients between the reflective layer 130 and the wavelength converter 140 disposed on the reflective layer 130, and thus the reliability of the LED package may be decreased.

In addition, the light extraction efficiency may be further improved by forming the reflective layer 130 to have the thickness W5, compared to an LED package according to the related art. Hereinafter, a detailed description thereof will be provided. In an LED package mounted in a flip-chip structure according to the related art, a relatively thick reflective layer is formed on a side of an LED chip and a wavelength converter is formed on the LED chip, in order to reflect side light from the LED chip and discharge the side light in a direction toward the substrate of the LED chip. Thus, an LED package according to the related art is designed so that light emitted from the LED chip is to be reflected by the reflective layer and be emitted in a direction toward the substrate of the LED chip. Such a reflective layer may be formed of a material having relatively high reflectance, but light is not totally reflected by the reflective layer because the reflectance thereof does not reach 100%. Thus, at least a part of the light emitted from the LED chip may penetrate the reflective layer or may be absorbed in the reflective layer.

Thus, light may be discharged out of the LED package without passing through the wavelength converter, which may lead to a problem in which light with an unwanted wavelength band may be irradiated on a light irradiation surface. For example, in the case of an LED package in which a wavelength of blue light emitted from a blue LED chip is converted to emit white light, a problem in which a band of blue light of which wavelength is not converted is irradiated on a light irradiation surface may be present. Thus, a color uniformity of light emitted from the LED package may be degraded, and light having a relatively low quality of color may be irradiated.

According to the present exemplary embodiment, the reflective layer 130 is not disposed to come into contact with the side of the LED chip 120, and thus the wavelength converter 140 may be disposed to come into contact with the side of the LED chip 120. Thus, a wavelength of the side light L emitted from the LED chip 120 may be converted in the wavelength converter 140 before the side light L is absorbed in or reflected by the reflective layer 130. Thus, the problem in which light in an unwanted wavelength band is irradiated may be prevented.

The wavelength converter 140 may be formed on one surface of the package substrate 110 to cover the LED chip 120 and at least a portion of the reflective layer 130, and may be formed using a light transmitting material in which a wavelength conversion material is dispersed. The wavelength converter 140 may protect the LED chip 120 from moisture and heat by covering the LED chip 120 therewith. In addition, light distribution of light emitted from the LED chip 120 may be controlled by adjusting a surface shape of the wavelength converter 140.

As illustrated in FIG. 2, the width W2 of the wavelength converter 140 may be greater than the width W1 of the LED chip 120 by about 1.3 times to about 3.7 times. In addition, as illustrated in FIG. 3, the wavelength converter 140 may be formed to cover the LED chip 120 and have an upper surface 141 and a side surface 142.

The upper surface 141 of the wavelength converter 140 may be formed to have a planar surface substantially parallel to an upper surface of the LED chip 120.

The side surface 142 of the wavelength converter 140 may be inclined with respect to the upper surface 141 of the wavelength converter 140 so that the side surface 142 may have a predetermined angle of inclination θ in a direction towards the upper surface 141 with respect to the one surface of the package substrate 110 on which the reflective layer is disposed. Here, the angle of the inclination θ may be between about 9.5° and about 36°. Here, portions of the side surface 142 of the wavelength converter 140 may be formed to have a curved surface.

In addition, a contact region P between the upper surface 141 and the side surface 142 of the wavelength converter 140 may be formed to be curved to prevent an edge from being formed in the contact region therebetween. In this case, reflection of light emitted from the LED chip 120 from the edge, which may lead to total internal reflection, may be prevented from occurring.

As the light transmitting material forming the wavelength converter 140, a transparent resin may be used. For example, the transparent resin may be one selected from a group consisting of silicone, modified silicone, epoxy, urethane, oxetane, acryl, polycarbonate, polyimide, and combinations thereof.

The wavelength converter 140 may be disposed to cover an entire surface of the reflective layer 130, but may not be disposed on a portion of the surface of the reflective layer 130 having a predetermined distance W4 from an outer end of the reflective layer 130. Thus, in this case, the surface of the reflective layer 130 may have a region coming in contact with the side surface of the wavelength converter 140. The reflective layer 130 may be disposed to be extended in an outward direction of the wavelength converter 140, based on the LED chip 120.

When the reflective layer 130 has a region on which the wavelength converter 140 is not disposed, as described above, the wavelength converter 140 may be formed to have a relatively small size, and thus, the amount of a wavelength conversion material used to form the wavelength converter 140 may be reduced. In general, wavelength conversion materials are relatively expensive, and the cost paid for the wavelength conversion material of the wavelength converter 140 may be a significant portion of the total cost for manufacturing an LED package. Therefore, the cost of manufacturing an LED package may be reduced by reducing the amount of the wavelength conversion material used to form the wavelength converter 140.

In addition, in a case in which the wavelength converter 140 has a lower portion in which the reflective layer 130 is not disposed due to a deviation occurring during a manufacturing process, the light extraction efficiency of the LED package may be decreased. However, when the wavelength converter 140 is not disposed on portions of the surface of the reflective layer 130 having a predetermined distance W4 from an outer end of the reflective layer 130, the formation of a region in which the reflective layer 130 is not disposed in the lower portion of the wavelength converter 140 may be prevented, and thus reduction in the light extraction efficiency of the LED package may be prevented.

The wavelength converter 140 may have a single-layer structure, but may have a multilayer structure in which a plurality of layers are laminated. When the wavelength converter 140 has a multilayer structure, light transmitting materials forming respective layers may have different characteristics from each other.

For example, a form of the wavelength converter 140 may be maintained stably by allowing a light transmitting material forming an upper layer to have a greater degree of strength than that of a light transmitting material forming a lower layer. In addition, when a light transmitting material forming a layer coming into contact with the LED chip 120 has an adhesive force greater than that of a light transmitting material forming an upper layer, the wavelength converter 140 may be easily adhered to the LED chip 120. Further, any one of the plurality of layers may be configured of a transparent layer not containing a wavelength conversion material.

A light transmitting material such as a phosphor or a quantum dot may be contained in the wavelength converter 140. As the phosphor, garnet-based phosphors (YAG, TAG, LuAG), silicate-based phosphors, nitride-based phosphors, sulfide-based phosphors, oxide-based phosphors, and the like may be used, and here, a single phosphor or a plurality of phosphors in which phosphors are mixed at a predetermined ratio may be used. According to an exemplary embodiment, at least red phosphor may be contained.

A lens 150 may be formed on the wavelength converter 140 to cover the wavelength converter 140. The lens 150 may be formed in various shapes so as to adjust distribution of light emitted from the LED chip 120. In detail, the lens 150 may have a convex, concave or oval shape, or the like.

A material forming the lens 150 is not particularly limited to a particular component as long as the material is a light transmitting substance, and a light transmitting insulation resin such as a silicone resin composition, a modified silicone resin composition, an epoxy resin composition, a modified epoxy resin composition, an acrylic resin composition, and the like may be applied thereto. In addition, a hybrid resin containing one or more of a silicone resin, an epoxy resin, and a fluorine resin may be used. The material of the lens 150 is not limited to an organic material, and an inorganic material having relatively great light resistance, such as glass, silica gel, or the like, may be used.

The LED package 100 having the aforementioned configuration may include the wavelength converter 140 with the inclined side surface 142, such that total reflection of the side light L emitted from the LED chip 120 inside the wavelength converter 140 may be reduced. Thus, the light extraction efficiency of the LED package 100 may be improved. In addition, since the wavelength converter 140 is disposed to completely cover the upper surface and the side of the LED chip 120, the problem in which the light emitted from the LED chip 120 is discharged outwardly without passing through the wavelength converter 140 may be prevented.

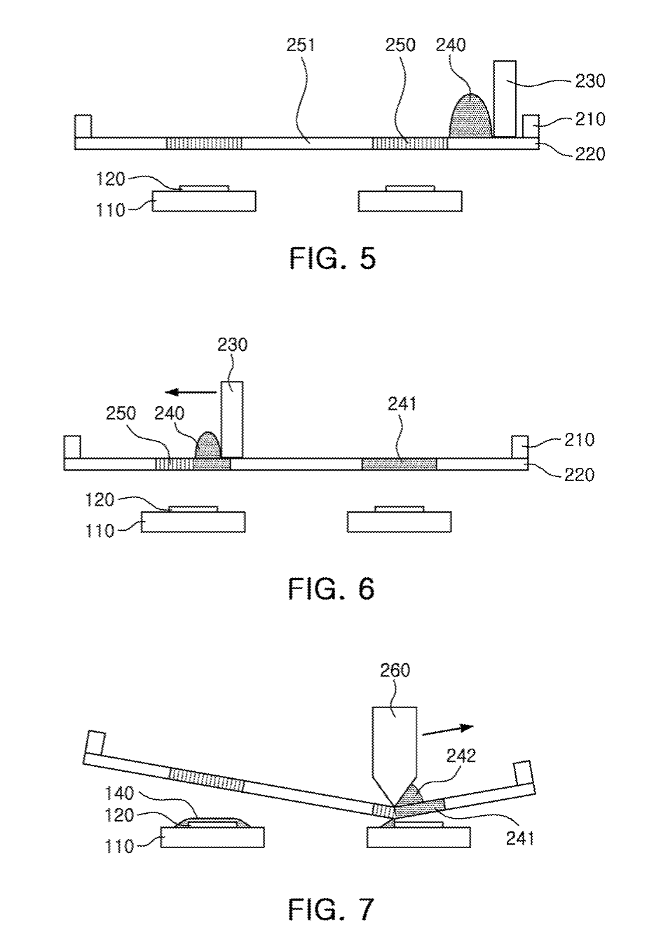

Hereinafter, a method of manufacturing the LED package of FIG. 1 will be described, referring to FIG. 5 to FIG. 8.

First, as illustrated in FIG. 5, a package substrate 110 on which an LED chip 120 is mounted may be prepared, and a screen mask 220 may be placed over the package substrate 110. Since the package substrate 110 and the LED chip 120 are described above, a detailed description thereof will be omitted.

The screen mask 220 may be formed of a metal thin film, which is elastic, and according to an exemplary embodiment, the screen mask 220 may be provided as a stainless steel (SUS) mesh structure which is, except printing regions 250, filled with an emulsion-type masking member 251. End portions of the screen mask 220 may be fixed to frames 210, and when a force is applied to the screen mask 220 during a subsequent process, the screen mask 220 may be extended elastically.

With this, in a subsequent process, a paste 240 to fill the printing region 250 of the screen mask 220 may be prepared, and a scraper 230 may be disposed on one end of the screen mask 220. The paste 240 may be a material to be hardened during a subsequent process to form a wavelength converter. The paste 240 as described above may be in a semi-hardened state at a room temperature and may have a form in which a wavelength conversion material is dispersed in a B-stage material phase-transformed to be able to flow at the time of heating. In detail, the B-stage material may be a compound formed by mixing a phosphor with a polymer binder formed of a resin, a hardener, a hardening catalyst, and the like, and then semi-hardening the mixture.

As the resin, an epoxy-based resin or an inorganic polymer silicone having high adhesion, great light transmission, superior heat resistance, strong photorefraction, good moisture tolerance, and the like may be used. In order to secure high adhesion, for example, a silane-based material may be used as an additive improving adhesive force.

A light transmitting material may be a phosphor or a quantum dot. As the phosphor, garnet-based phosphors (YAG, TAG, LuAG), silicate-based phosphors, nitride-based phosphors, sulfide-based phosphors, oxide-based phosphors, and the like may be used, and the light transmitting material may be formed of a single phosphor or a plurality of phosphors in which respective phosphors are mixed at a predetermined ratio. According to an exemplary embodiment, at least a red phosphor may be contained therein.

As illustrated in FIG. 6, the scraper 230 may be moved from one end to the other end of the screen mask 220. Then, a paste-filled part 241 may be formed as the paste 240 formed of a semi-hardened material is filled in the mesh of the printing region 250.

Next, as illustrated in FIG. 7, a squeegee 260 may be moved in a direction opposite to the direction of the movement of the scraper 230 performed in the previous process. As the squeegee 260 is moved pushing the paste-filled part 241, the paste 240 may cover the LED chip 120 mounted on the package substrate 110. Here, when the covered paste is hardened, the wavelength converter 140 may be formed. Remaining paste not being used for covering is moved to one end of the screen mask 220 as the squeegee 260 is moved. Since the paste is in a semi-hardened state, when the paste 242 covers the LED chip 120, an inclined surface may be naturally formed by surface tension. Thus, an inclined surface may be formed during the covering process, without a mold. Thus, an inclined surface of the wavelength converter 140 may be easily formed.

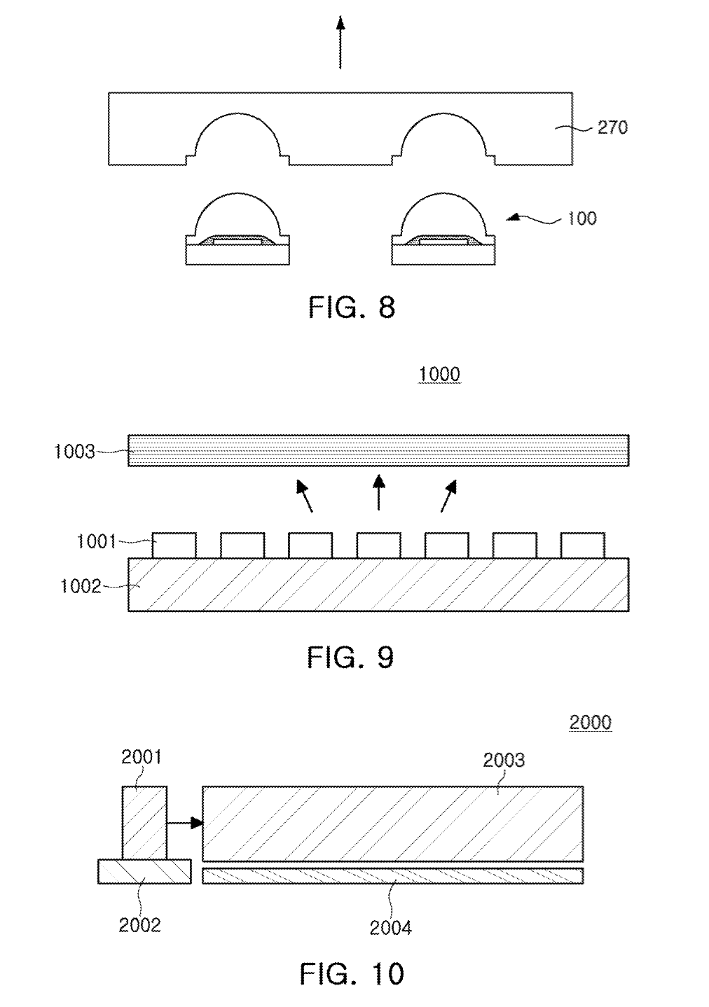

Next, a lens covering the wavelength converter 140 may be formed using a mold 270, as illustrated in FIG. 8.

In the method of manufacturing an LED package having the aforementioned configuration, the wavelength converter may be disposed to seamlessly cover sides of the LED chip, such that the quality of color may be improved in the LED package. In addition, the wavelength converter of the LED package according to the above exemplary embodiments may be relatively easily manufactured as compared to a wavelength converter of an LED package according to the related art, and an unnecessary waste of the wavelength conversion material may be avoided in the manufacturing process. Thus, manufacturing costs may be reduced. Further, the inclined surfaces of the wavelength converter may be naturally formed without a mold during a process of applying the paste using the screen mask 220, such that the light extraction efficiency of the LED package may be improved.

FIG. 9 and FIG. 10 are views illustrating backlight units to which a light emitting device module according to the above exemplary embodiments is applied.

Referring to FIG. 9, in a backlight unit 1000, light sources 1001 may be mounted on a substrate 1002, and one or more optical sheets 1003 may be disposed above the light sources 1001. As the light source 1001, the LED package described above may be used.

In the backlight unit 1000 of FIG. 9, the light sources 1001 may radiate light upwardly, toward a liquid crystal display device. On the other hand, in a backlight unit 2000 of FIG. 10 in another example, a light source 2001 mounted on a substrate 2002 may radiate light in a lateral direction, such that the radiated light may be incident on a light guide panel 2003 to be converted into a surface light source. The light passing through the light guide panel 2003 may be discharged in an upper direction, and in order to improve light extraction efficiency, a reflective layer 2004 may be disposed below the light guide panel 2003.

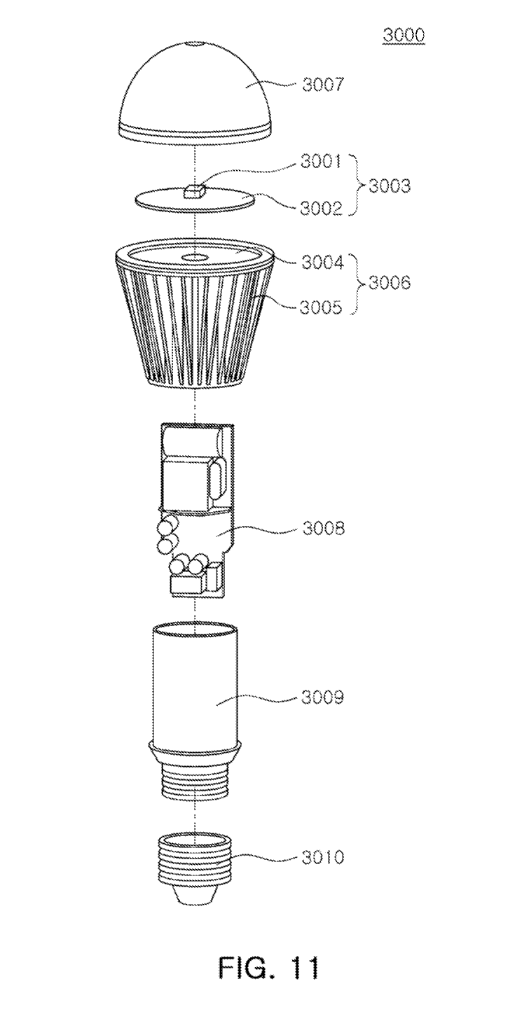

FIG. 11 is an exploded perspective view illustrating an example of a lighting device to which a light emitting device package according to the above exemplary embodiments are applied.

A lighting device 3000 illustrated in FIG. 11 is illustrated as a bulb-type lamp and may include a light emitting module 3003, a driver 3008, and an external connector 3010.

In addition, the lighting device 3000 may further include exterior structures such as an external housing 3006, an internal housing 3009, and a cover unit 3007. The light emitting module 3003 may include a light source 3001 having the same structure as the structure of the aforementioned semiconductor LED package or a structure similar thereto, and a circuit board 3002 having the light source 3001 mounted thereon. For example, the first and second electrodes of the aforementioned semiconductor light emitting device may be electrically connected to an electrode pattern of the circuit board 3002. In the present exemplary embodiment, a single light source 3001 is mounted on the circuit board 3002 by way of example, but a plurality of light sources may be mounted thereon as necessary.

The external housing 3006 may serve as a heat radiator and may include a heat sink plate 3004 coming into direct contact with the light emitting module 3003 to thereby improve heat dissipation, and heat radiating fins 3005 surrounding a side surface of the lighting device 3000. The cover unit 3007 may be mounted on the light emitting module 3003 and have a convex lens shape. The driver 3008 may be disposed inside the internal housing 3009 and be connected to the external connector 3010 having a socket-like structure to receive power from an external power source. In addition, the driver 3008 may convert the received power into power appropriate for driving the light source 3001 of the light emitting module 3003 and supply the converted power. For example, the driver 3008 may be configured of an AC-DC converter, a rectifying circuit part, or the like.

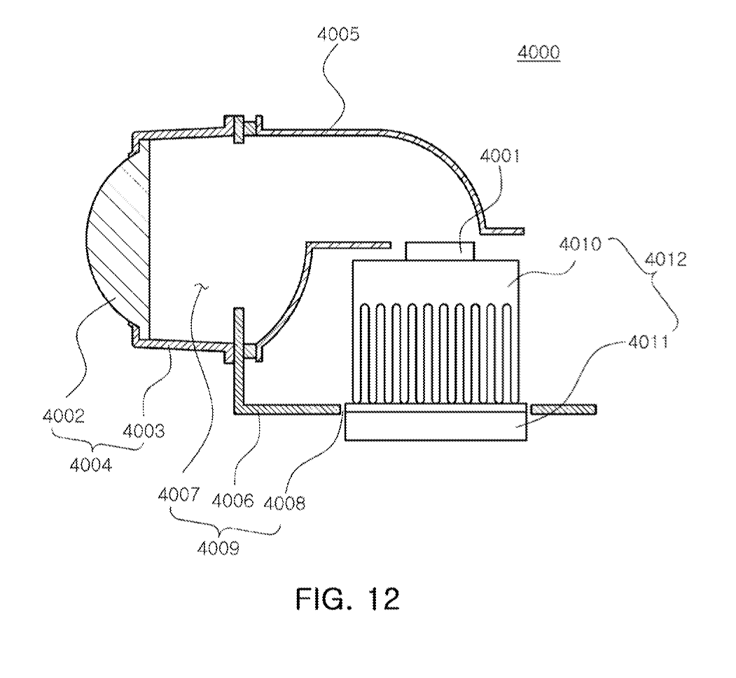

FIG. 12 illustrates an example of a vehicle headlamp to which an LED package according to the above exemplary embodiment are applied.

With reference to FIG. 12, a vehicle headlamp 4000 used in a vehicle or the like may include a light source 4001, a reflector 4005 and a lens cover 4004, and the lens cover 4004 may include a hollow guide part 4003 and a lens unit 4002. The light source 4001 may include the aforementioned LED package.

The headlamp 4000 may further include a heat radiator 4012 externally radiating heat generated by the light source 4001. The heat radiator 4012 may include a heat sink 4010 and a cooling fan 4011 to effectively radiate heat. In addition, the vehicle headlamp 4000 may further include a housing 4009 allowing the heat radiator 4012 and the reflector 4005 to be fixed thereto and supported thereby. The housing 4009 may include a body 4006 and a central hole 4008 formed in one surface thereof to which the heat radiator 4012 is coupled.

The housing 4009 may include a forwardly open hole 4007 formed in a surface thereof that is integrally connected to the one surface thereof and is bent in a direction perpendicular thereto, so that the reflector 4005 may be fixedly disposed at an upper side of the light source 4001. Thus, a front side may be opened by the reflector 4005, and the reflector 4005 may be fixed to the housing 4009 so that the open front side corresponds to the forwardly open hole 4007, such that light reflected by the reflector 4005 may pass through the forwardly open hole 4007 and be emitted externally.

As set forth above, the quality of color may be improved in an LED package according to the above exemplary embodiments.

While various exemplary embodiments have been shown and described above, it will be apparent to those skilled in the art that modifications and variations could be made without departing from the scope of the inventive concept as defined by the appended claims.

What is claimed is:

1. A light emitting diode (LED) package comprising:
a package substrate having a first electrode structure and a second electrode structure;
an LED chip disposed above a first surface of the package substrate and having a first electrode attached to the first electrode structure and a second electrode attached to the second electrode structure;
a reflective layer disposed above the first surface of the package substrate to be separated from the LED chip, having a thickness less than a thickness of the LED chip, and configured to reflect light emitted from the LED chip to a given direction; and
a wavelength converter covering the LED chip and at least a portion of the reflective layer, and configured to convert a wavelength of the light emitted from the LED chip;
wherein the wavelength converter includes:
an upper surface substantially parallel to the first surface of the package substrate; and
a side surface inclined towards the upper surface.

2. The LED package of claim 1, wherein a distance between a side end of the LED chip closest to the reflective layer and the reflective layer in a direction parallel with the first surface of the package substrate ranges from about 50 μm to about 150 μm.

3. The LED package of claim 1, wherein a thickness of the reflective layer ranges from about 20 μm to about 60 μm.

4. The LED package of claim 1, wherein the reflective layer contains at least one of SiO₂, SiN, SiOₓN_{y}, TiO₂, Si₃N₄, Al₂O₃, TiN, AlN, ZrO₂, TiAlN, and TiSiN.

5. The LED package of claim 1, wherein the inclined side surface of the wavelength converter has an angle of inclination ranging from about 9.5° to about 36°, inclined in a direction from a bottom of the wavelength converter towards the upper surface of the wavelength converter with respect to the first surface of the package substrate.

6. The LED package of claim 1, wherein a portion of the wavelength converter at which the upper surface of the wavelength converter and the side surface of the wavelength converter are connected is curved.

7. The LED package of claim 1, wherein the reflective layer is disposed to come into contact with the inclined side surface of the wavelength converter and to extend outwardly from the wavelength converter, based on the LED chip, and
wherein at least a portion of the reflective layer is not covered by the wavelength converter.

8. The LED package of claim 1, wherein a side of the LED chip is covered by the wavelength converter.

9. The LED package of claim 1, wherein the wavelength converter is formed of a light transmitting material in which a wavelength conversion material is dispersed.

10. The LED package of claim 9, wherein the light transmitting material is a material selected from a group consisting of silicone, modified silicone, an epoxy, a urethane, oxetane, an acryl, a polycarbonate, a polyimide, and combinations thereof.

11. The LED package of claim 9, wherein the wavelength conversion material is a phosphor or a quantum dot.

12. The LED package of claim 1, further comprising a lens covering the wavelength converter.

13. The LED package of claim 1, wherein a width of the wavelength converter is greater than a width of the light emitting diode chip by about 1.3 times to about 3.7 times.

14. A light emitting diode (LED) package comprising:
a package substrate;
an LED chip mounted on a first surface of the package substrate;
a reflective layer disposed above the first surface of the package substrate to be spaced apart from the LED chip by a predetermined distance, and configured to reflect light emitted from the LED chip to a given direction; and
a wavelength converter covering the LED chip and at least a portion of the reflective layer, having a side surface inclined downwardly towards the first surface of the package substrate, and configured to convert a wavelength of the light emitted from the LED chip.

15. The LED package of claim 14, wherein the LED chip is mounted above the first surface of the package substrate in a flip-chip structure.

16. The LED package of claim 14, wherein the wavelength converter does not entirely cover the reflective layer.

17. The LED package of claim 14, wherein the reflective layer is spaced apart from the LED chip by a predetermined distance when viewed from above the LED package so that the light emitted from the LED chip is not discharged without passing through the wavelength converter.

18. The LED package of claim 14, wherein the reflective layer is not disposed in an optical path of the light emitted from the LED chip which is parallel with the first surface of the package substrate.

19. The LED package of claim 14, wherein a thickness of the reflective layer is less than a thickness of the LED chip.

20. The LED package of claim 14, the LED chip comprises:
a light transmitting substrate;
a first conductivity-type semiconductor layer;
an active layer;
a second conductivity-type semiconductor layer; and
first and second electrode,
wherein a surface of the light transmitting substrate facing the first conductivity-type semiconductor layer is an uneven surface.
